(19) United States
(12) Patent Application Publication
(10) Pub. No.: US 2026/0053013 A1
(43) Pub. Date: Feb. 19, 2026

(54) PACKAGE STRUCTURE AND METHOD FOR FABRICATING THE SAME

(71) Applicant: Taiwan Semiconductor Manufacturing Company, Ltd., Hsinchu (TW)

(72) Inventors: Chia-Jen CHENG, New Taipei City (TW); Kuo-Ching HSU, Taipei (TW); Mirng-Ji LII, Sinpu Township (TW)

(21) Appl. No.: 18/804,469

(22) Filed: Aug. 14, 2024

(51) Int. Cl. H01L 23/538; H01L 21/48; H01L 23/00; H01L 23/13; H01L 23/15; H01L 25/00; H01L 25/065

(52) U.S. Cl. CPC H01L 23/5385; H01L 21/4857; H01L 23/13; H01L 24/32; H01L 25/0655; H01L 25/50; H01L 23/15; H01L 24/16; H01L 24/73; H01L 2224/16238; H01L 2224/32225; H01L 2224/73204

(57) ABSTRACT

A package structure is provided. The package structure includes a package substrate, an inorganic substrate over the package substrate, and a package component over the inorganic substrate. The package structure includes a plurality of conductive connectors penetrating the inorganic substrate and electrically connected to the package component and the package substrate. The package structure also includes an underfill formed around the conductive connectors and between the package component and the inorganic substrate.

### BACKGROUND

The semiconductor industry has experienced rapid growth due to ongoing improvements in the integration density of a variety of electronic components (e.g., transistors, diodes, resistors, capacitors, etc.). For the most part, improvement s in integration density have resulted from iterative reductions of minimum feature size, which allows more components to be integrated into a given area. As the demand for shrinking electronic devices has grown, a need for smaller and more creative packaging techniques of semiconductor dies has emerged. An example of such packaging systems is Package-on-Package (PoP) technology. In a PoP device, a top semiconductor package is stacked on top of a bottom semiconductor package to provide a high level of integration and component density. PoP technology generally enables production of semiconductor devices with enhanced functionalities and small footprints on a printed circuit board (PCB).

Although existing package structures have generally been adequate for their intended purposes, they have not been entirely satisfactory in all respects.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1A through 1H illustrates cross-sectional views of intermediate steps during a process for fabricating a package structure in accordance with some embodiments.

FIG. 2A illustrates an enlarged view of the region A shown in FIG. 1H in accordance with some embodiments.

FIG. 2B illustrates an enlarged view of the region B shown in FIG. 1H in accordance with some embodiments.

FIG. 3 illustrates a top view of the package structure in accordance with some embodiments.

FIG. 4 illustrates a cross-sectional view of the package structure in accordance with some embodiments.

FIG. 5 illustrates a cross-sectional view of the package structure in accordance with some embodiments.

FIG. 6 illustrates a cross-sectional view of the package structure in accordance with some embodiments.

FIG. 7 illustrates a cross-sectional view of the package structure in accordance with some embodiments.

FIG. 8 illustrates a cross-sectional view of the package structure in accordance with some embodiments.

FIG. 9 illustrates a cross-sectional view of the package structure in accordance with some embodiments.

FIG. 10 illustrates a cross-sectional view of the package structure in accordance with some embodiments.

FIG. 11 illustrates a top view of the package structure in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numbers are used to designate like elements. It should be understood that additional operations can be provided before, during, and after the method, and some of the operations described can be replaced or eliminated for other embodiments of the method.

Embodiments of package structures and method for fabricating the same are provided. The package structure includes an inorganic substrate over the package substrate. For example, the inorganic substrate may be made of alkaline earth boro-aluminosilicate, including elements such as Si, B, Al, Be, Ca, Na, O, etc. The arrangement of the inorganic substrate may help to reduce the coefficients of thermal expansion (CTE) mismatch between the substrate and the chips. Accordingly, the package reliability may be improved. In addition, a plurality of vent holes may be formed in the inorganic substrate so as to facilitate the gas or moisture discharged from the underlying substrate. Furthermore, a trench may be formed in the inorganic substrate so as to contain overflowing molding material (if present).

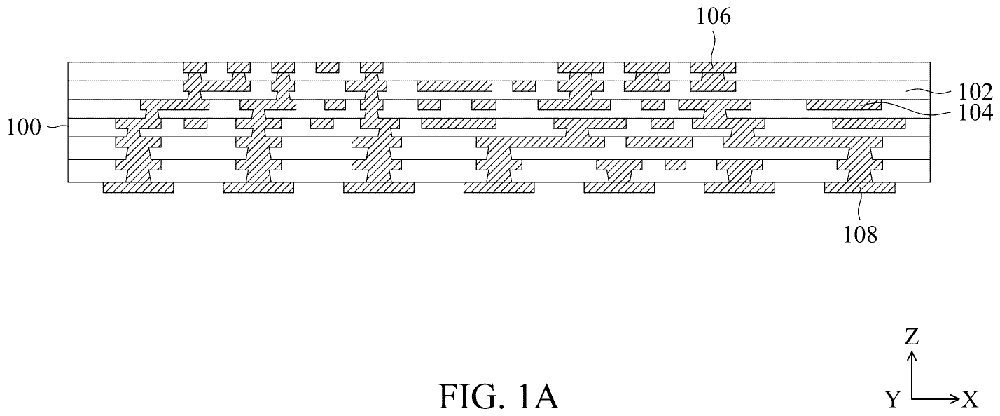

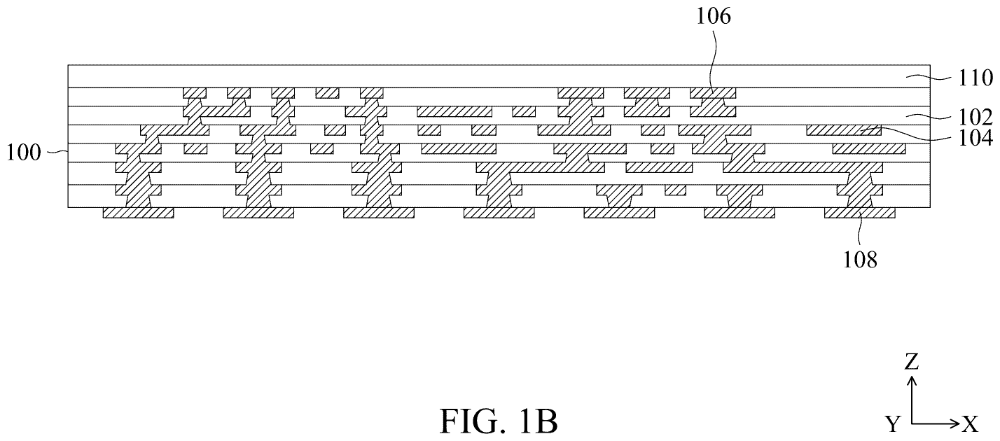

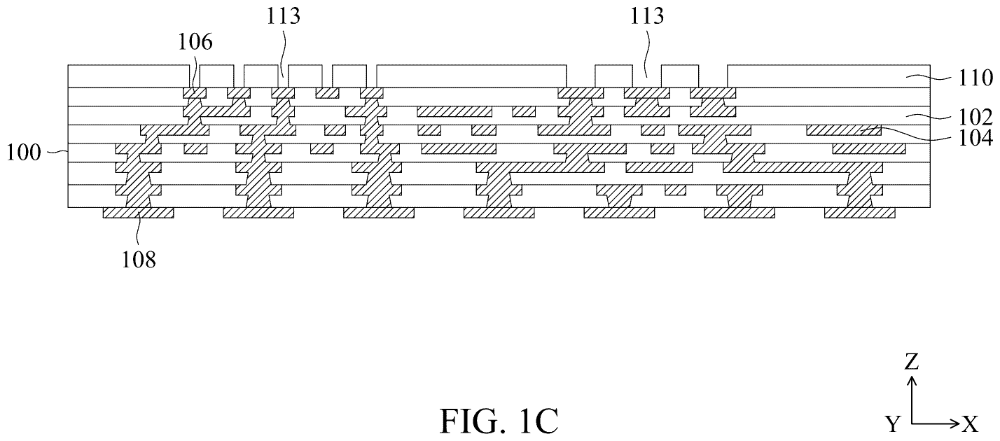

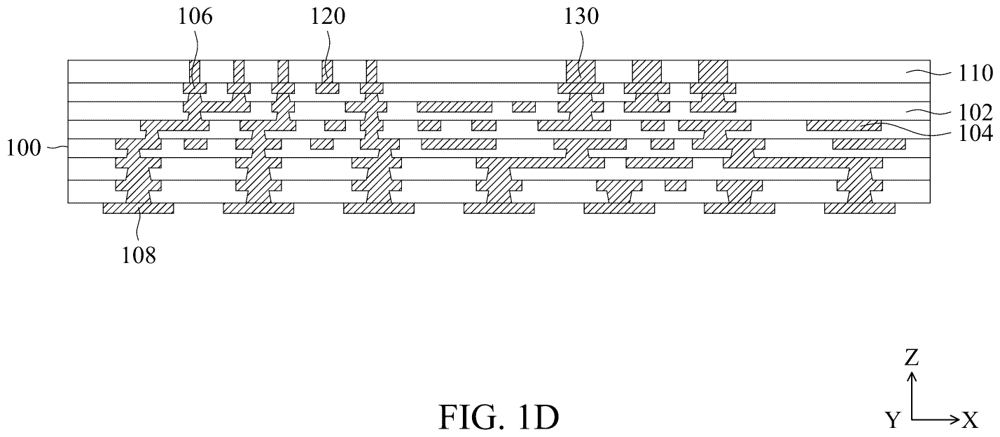

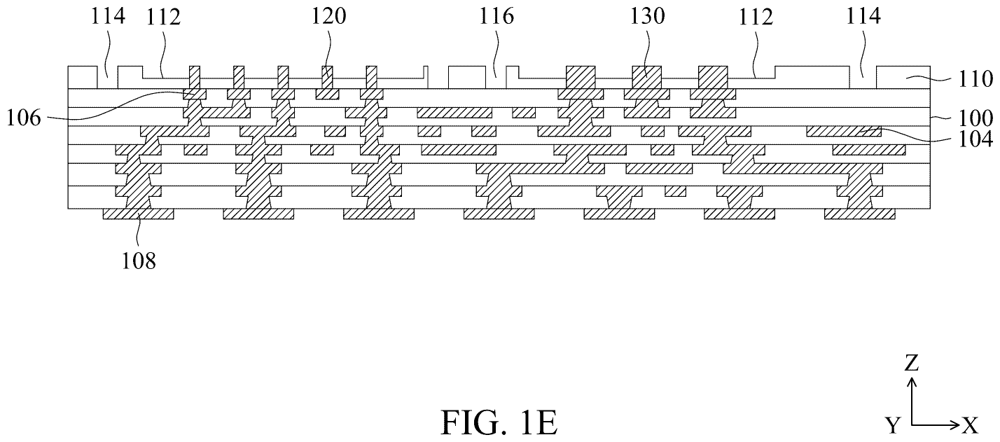

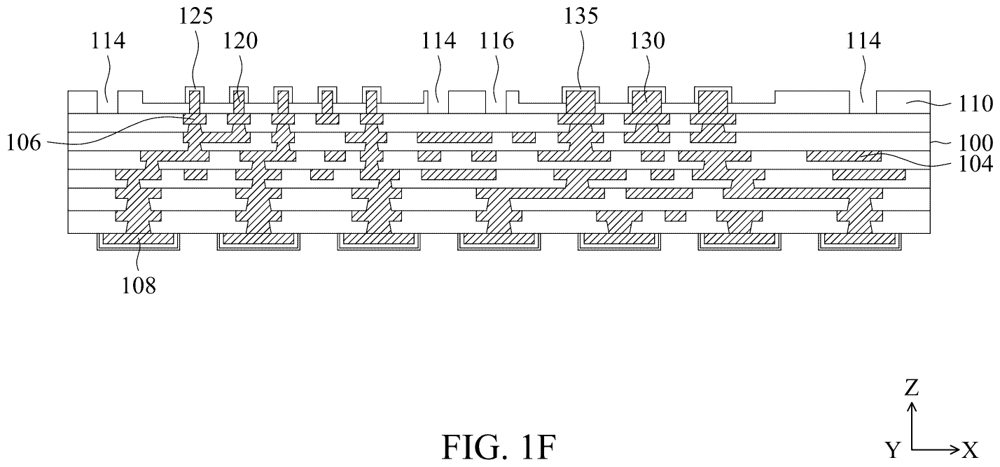

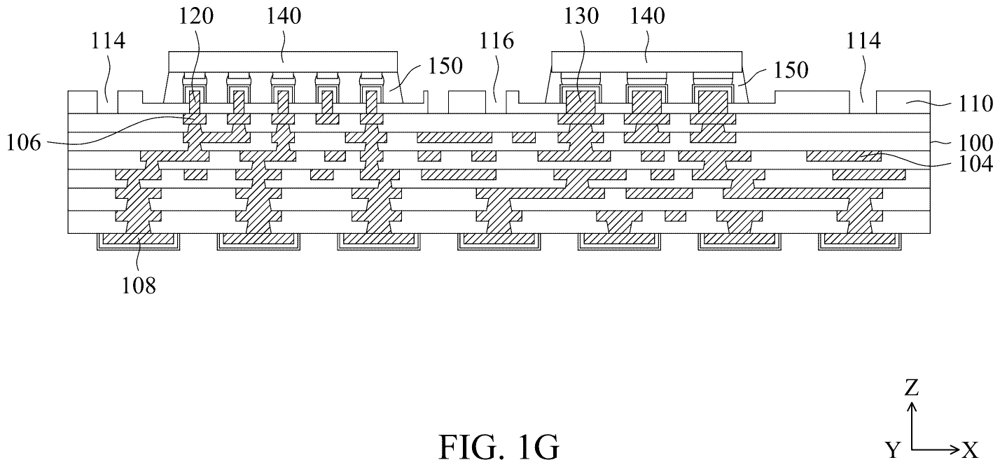

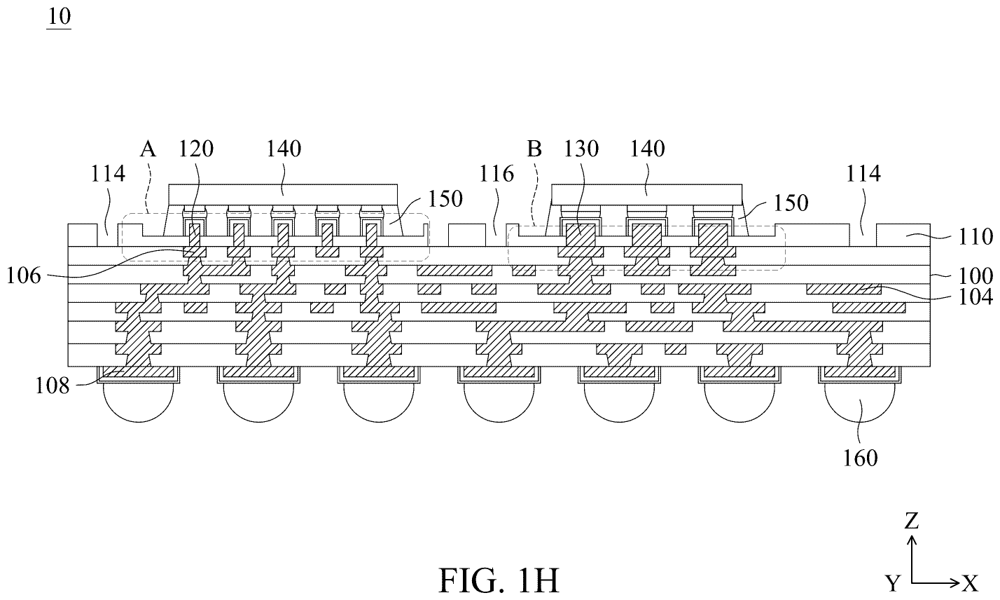

FIGS. 1A through 1H illustrates cross-sectional views of intermediate steps during a process for fabricating a package structure 10 in accordance with some embodiments. As shown in FIG. 1A, a package substrate 100 is provided. In some embodiments, the package substrate 100 includes a plurality of dielectric layers 102 and a plurality of conductive patterns 104 that are formed in the dielectric layers 102. In some embodiments, the dielectric layers 102 include a polymer such as polybenzoxazole (PBO), polyimide, benzocyclobutene (BCB), or the like; a nitride such as silicon nitride or the like; an oxide such as silicon oxide, phosphosilicate glass (PSG), borosilicate glass (BSG), boron-doped phosphosilicate glass (BPSG), undoped silicate glass (USG), or the like, or a combination thereof. It should be understood that all possible materials for the dielectric layers 102 are included within the scope of the present disclosure. In some embodiments, the dielectric layers 102 are formed, for example, by spin coating, lamination, chemical vapor deposition (CVD), or the like. In some embodiments, the dielectric layers 102 may be formed using different materials or processes. However, the present disclosure is not limited thereto.

As an example of the formation of the conductive patterns 104, a seed layer is formed in the through holes extending through the dielectric layer 102. In some embodiments, the seed layer is a metal layer, which may be a single layer or a composite layer comprising a plurality of sub-layers formed of different materials. In some embodiments, the seed layer comprises a titanium layer and a copper layer over the titanium layer. In some embodiments, the seed layer is formed using, for example, physical vapor deposition (PVD) or the like. A photoresist is then formed and patterned on the seed layer. In some embodiments, the photoresist is formed by spin coating or the like and may be exposed to light for patterning. The pattern of the photoresist corresponds to the conductive patterns 104. The patterning forms openings through the photoresist to expose the seed layer. A conductive material is then formed in the openings of the photoresist and on the exposed portions of the seed layer. In some embodiments, the conductive material is formed by plating, such as electroplating or electroless plating, or the like. In some embodiments, the conductive material includes a metal, like copper, titanium, tungsten, aluminum, or the like. The combination of the conductive material and underlying portions of the seed layer form the conductive patterns 104. The photoresist and portions of the seed layer on which the conductive material is not formed are removed. In some embodiments, the photoresist is removed by an acceptable ashing or stripping process, such as using an oxygen plasma or the like. Once the photoresist is removed, exposed portions of the seed layer are removed, such as by using an acceptable etching process, such as by wet or dry etching.

In some embodiments, the package substrate 100 includes a plurality of contact pads 106 and another plurality of contact pads 108 for external connection. The contact pads 106 and the contact pads 108 may be formed on opposite sides of the package substrate 100. For example, the contact pads 106 may be formed in and exposed from the uppermost dielectric layer 102, and the contact pads 108 may be formed on the bottommost dielectric layer 102. However, the present disclosure is not limited thereto. In some embodiments, the formation of the contact pads 106 and the contact pads 108 may be similar to that of the conductive patterns 104. However, the present disclosure is not limited thereto.

Then, as shown in FIG. 1B, an inorganic substrate 110 may be disposed over the package substrate 100. For example, the inorganic substrate 110 may be attached to the package substrate 100 via semi-solid adhesive (for example, epoxy), and the adhesive is cured by reflow process. In some embodiments, the inorganic substrate 110 may be made of alkaline earth boro-aluminosilicate, including elements such as Si, B, Al, Be, Ca, Na, O, etc. The arrangement of the inorganic substrate may help to reduce the coefficients of thermal expansion (CTE) mismatch between the substrate (for example, the package substrate 100) and the chips (for example, the package components 140 to be bonded). Accordingly, the package reliability may be improved. In some embodiments, the coefficients of thermal expansion of the inorganic substrate 110 may be between those of the package substrate 100 and the package components 140. Because of the material property of the inorganic substrate 110, the inorganic substrate 110 may also be referred to as the glass substrate 110 in the following paragraphs.

Then, as shown in FIG. 1C, a plurality of openings 113 are formed in the inorganic substrate 110. In some embodiments, the openings 113 are formed by etching, laser drilling, oy any other suitable method. In some embodiments, the widths and the spacings of the openings 113 may be variant depending upon the desired conductive connectors to be formed. That is to say, the dimensions and the locations of the openings 113 may be adjustable based on the present disclosure. In some embodiments, the openings 113 may be located within and partially expose the underlying contact pads 106.

Next, as shown in FIG. 1D, a conductive material may be filled into the openings 113 to form a plurality of conductive connectors 120 and 130. As an example to form the conductive connectors 120 and 130, the conductive material is formed in the openings 113 by plating and in contact with the underlying contact pads 106 for electrical connection. In some embodiments, a planarization process (for example, chemical mechanical polish (CMP) process) may be performed to the conductive connectors 120 and 130 so that the top surface of the conductive connectors 120 and 130 may be substantially level with the inorganic substrate 110. It should be noted that the configuration of the conductive connectors 120 and 130 merely serves as an example, and the present disclosure is not limited thereto.

As shown in FIG. 1E, a plurality of recesses 112 may be formed by selectively etching the inorganic substrate 110 for receiving the package component 140 (for example, referring to FIG. 1G) to be bonded. In some embodiments, forming the recesses 112 includes partially exposing the sidewalls of the conductive connectors 120 and 130. The dimensions (such as length and width) of the recess es 112 may be greater than the dimensions of the package component 140, leaving sufficient tolerance for bonding the package component 140. In some embodiments, one recess 112 is configured to receive single package component 140. However, the present disclosure is not limited thereto. In some other embodiments, one recess 112 is configured to receive multiple package components 140.

In addition, a plurality of vent holes 114 are formed in the inorganic substrate 110. In some embodiments, the vent holes 114 are located outside the recesses 112. However, the present disclosure is not limited thereto. The vent holes 114 penetrate the inorganic substrate 110 and expose the underlying package substrate 100 (such as the dielectric layer 102). In this way, gas or moisture may be discharged from the package substrate 100 without being blocked by the inorganic substrate 110. Furthermore, a trench 116 is formed in the inorganic substrate 110. In some embodiments, the trench 116 may be formed between the adjacent recesses 112 (i.e., between the adjacent package components 140). The trench 116 may be configured to provide buffer space for the subsequently formed underfill 150 or molding material (not shown). In some embodiments, the trench 116 may penetrate the inorganic substrate 110 and expose the underlying package substrate 100 (such as the dielectric layer 102). However, the present disclosure is not limited thereto. In some embodiments, the trench 116 may not expose the underlying package substrate 100.

Then, as shown in FIG. 1F, a surface treatment process may be performed to the conductive connectors 120 and 130 and the contact pads 108. For example, the surface treatment process may include electroless nickel-electroless palladium-immersion gold (ENEPIG) process, organic solderability preservative (OSP) process, or any other suitable process. Accordingly, the risk that oxidation occurs to the conductive connectors 120 and 130 may be reduced, and therefore the performance or reliability of the package structure 10 may be enhanced. As a result, a treated portion 125 may be formed on each of the conductive connectors 120, and another treated portion 135 may be formed on each of the conductive connectors 130. In some embodiments, the treated portions 125 and 135 may be formed to have a thickness in a range from about 0.1 μm to about 10 μm. The treated portions 125 and 135 may include metallic materials, depending on the surface treatment process performed to the conductive connectors 120 and 130. It should be noted that for the sake of brevity, the treated portions 125 and 135 will not be individually shown in the following figures and considered as a part of the conductive connectors 120 and 130.

Next, as shown in FIG. 1G, a plurality of package components 140 are bonded to the conductive connectors 120 and 130. In some embodiments, the package components 140 include a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof.

In some embodiments, the package components 140 are formed in a wafer, which may include different device regions that are singulated in subsequent steps to form a plurality of integrated circuit dies. In some embodiments, the package components 140 are processed according to applicable manufacturing processes to form integrated circuits. For example, the package components 140 include a semiconductor substrate, such as silicon, doped or undoped, or an active layer of a semiconductor-on-insulator (SOI) substrate. In some embodiments, the semiconductor substrate includes other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. In some embodiments, the package components 140 are stacked devices that includes multiple semiconductor substrates. For example, the package components 140 may be a memory device such as a hybrid memory cube (HMC) module, a high bandwidth memory (HBM) module, or the like that includes multiple memory dies.

In the embodiment shown, multiple package components 140 are adhered adjacent one another. For example, one of the package components 140 may be a logic device, such as a central processing unit (CPU), a graphics processing unit (GPU), a system-on-a-chip (SoC), a microcontroller, or the like. The other package components 140 may be a memory device, such as a dynamic random access memory (DRAM) die, a static random access memory (SRAM) die, a hybrid memory cube (HMC) module, a high bandwidth memory (HBM) module, or the like. In some embodiments, the package components 140 are the same type of dies, such as SoC dies. In some embodiments, the package components 140 are formed in the processes of the same technology node, or they are formed in the processes of different technology nodes. For example, one of the package components 140 may be of a more advanced process node than the other of the package components 140. The package components 140 may be different sizes (e.g., different heights and/or surface areas), or they may be the same size (e.g., the same height and/or surface area).

Next, as shown in FIG. 1G, an underfill 150 is formed around the conductive connectors 120 and 130, and is located between the package components 140 and the inorganic substrate 110. In some embodiments, the underfill 150 is formed by a capillary flow process after the package components 140 are attached or is formed by a suitable deposition method before the package components 140 are attached. In some embodiments, the underfill 150 is formed in the recess 112 of the inorganic substrate 110, reducing the risk that the underfill 150 overflows. In some embodiments, a molding material (not shown) is selectively formed around the package components 140 and the underfill 150. After formation, the molding material encapsulates the conductive connectors 120 and 130 and the package components 160. In some embodiments, the molding material may include a molding compound, epoxy, or the like. In some embodiments, the molding material is applied by compression molding, transfer molding, or the like. In some embodiments, the molding material is applied in liquid or semi-liquid form and then subsequently cured. In some embodiments, a planarization step may be performed to remove and planarize an upper surface of the molding material.

Then, as shown in FIG. 1H, a plurality of conductive connectors 160 are formed on the contact pads 108. The conductive connectors 160 may be ball grid array (BGA) connectors, solder balls, controlled collapse chip connection (C4) bumps, micro bumps, electroless nickel-electroless palladium-immersion gold technique (ENEPIG) formed bumps, or the like. In some embodiments, the conductive connectors 160 include a conductive material such as solder, copper, aluminum, gold, nickel, silver, palladium, tin, the like, or a combination thereof. In some embodiments, the conductive connectors 160 are formed by initially forming a layer of solder through evaporation, electroplating, printing, solder transfer, ball placement, or the like. Once a layer of solder has been formed on the structure, a reflow may be performed in order to shape the material into the desired bump shapes. Accordingly, a package structure 10 may be formed.

It should be noted that although the package structure 10 is illustrated in FIG. 1H, it is not intended to limit the scope of the present disclosure. Those skilled in the art would realize that other components may be added to the package structure 10 for achieving particular function, and these configurations are also included within the scope of the present disclosure.

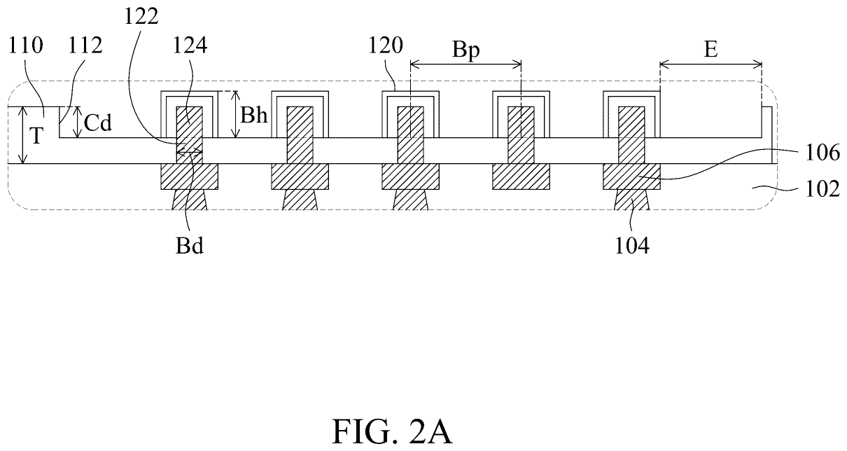

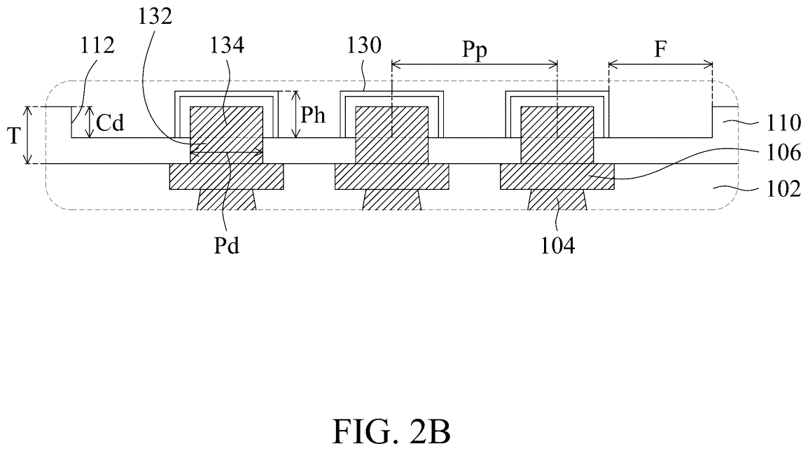

FIG. 2A illustrates an enlarged view of the region A shown in FIG. 1H in accordance with some embodiments. As shown in FIG. 2A, the thickness T of the inorganic substrate 110 may be in a range from about 20 μm to about 250 μm. As a result, the inorganic substrate 110 may be sufficient to reduce the coefficients of thermal expansion (CTE) mismatch between the package substrate 100 and the package components 140, and the cost of the inorganic substrate 110 is still be acceptable. In some embodiments, the depth Cd of the recess 112 may be in a range from 0 to about 248 μm. In some embodiments, the conductive connectors 120 each include a via portion 122 embedded in the inorganic substrate 110 and a pad portion 124 over the inorganic substrate 110. The pad portion 124 is electrically connected to the corresponding via portion 122. In some embodiments, the height Bh of the pad portion 124 may be in a range from 0 to about 20 μm. The diameter Bd of the via portion 122 may be in a range from about 10 μm to about 100 μm. The pitch Bp of the conductive connectors 120 may be in a range from about 20 μm to about 200 μm. The distance E between the edge of the recess 112 to the adjacent conductive connector 120 may be in a range from about 250 μm to about 3000 μm. It should be noted that the above dimensions may be adjustable depending on the package component 140, and the present disclosure is not limited thereto. As a result, the package component 140 may be bonded to the conductive connectors 120 more smoothly.

FIG. 2B illustrates an enlarged view of the region B shown in FIG. 1H in accordance with some embodiments. As shown in FIG. 2B, the conductive connectors 130 each include a via portion 132 embedded in the inorganic substrate 110 and a pad portion 134 over the inorganic substrate 110. The pad portion 134 is electrically connected to the corresponding via portion 132. In some embodiments, the height Ph of the pad portion 134 may be in a range from 0 to about 20 μm. The diameter Pd of the via portion 132 may be in a range from about 100 μm to about 500 μm. The pitch Pp of the conductive connectors 130 may be in a range from about 200 μm to about 1000 μm. The distance F between the edge of the recess 112 to the adjacent conductive connector 130 may be in a range from about 250 μm to about 3000 μm. It should be noted that the above dimensions may be adjustable depending on the package component 140, and the present disclosure is not limited thereto. As a result, the package component 140 may be bonded to the conductive connectors 130 more smoothly.

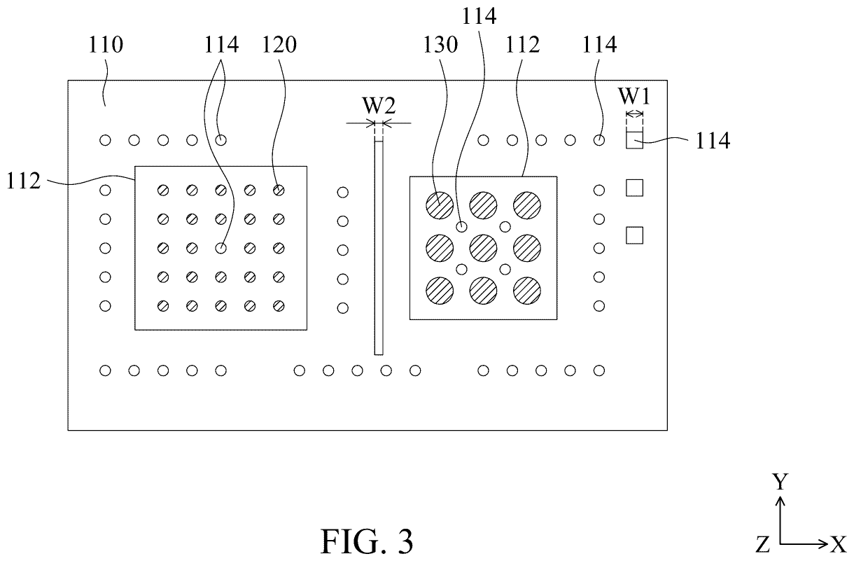

FIG. 3 illustrates a top view of the package structure in accordance with some embodiments. As shown in FIG. 3, the vent holes 114 are distributed across the inorganic substrate 110. In some embodiments, the vent holes 114 may be located around the recesses 112. However, the present disclosure is not limited thereto. In some embodiments, the vent holes 114 may be distributed in the recesses 112. For example, the profile of the vent holes 114 in the top view may be circular, rounded rectangular, etc. In some embodiments, the width W1 (or the diameter) of the vent holes 114 may be ranged from about 10 μm to about 200 μm. In addition, the trench 116 may be formed between the adjacent recesses 112 (i.e., between the adjacent package components 140). In some embodiments, the trench 116 extends in parallel with an edge of the recess 112. In some embodiments, the width W2 of trench 116 is ranged from about 25 μm to about 100 μm. It should be noted that the configuration of the vent holes 114 and the trench 116 is not limited within the scope of the present embodiment.

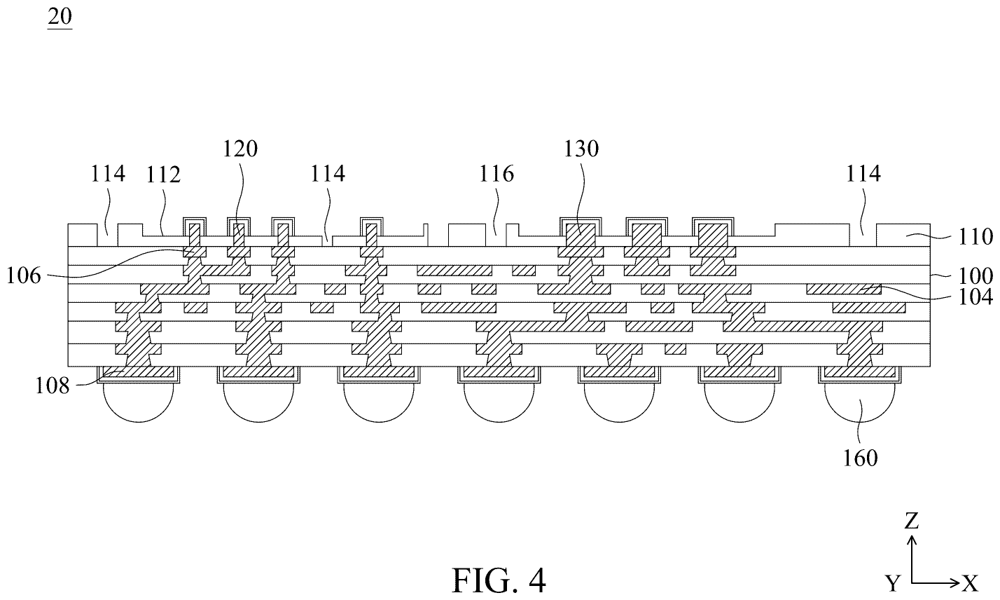

FIG. 4 illustrates a cross-sectional view of the package structure 20 in accordance with some embodiments. It should be noted that the package structure 20 in this embodiment may include the same or similar portions or elements as those of the package structure 10 in FIG. 1. For the sake of brevity, these portions or elements will be denoted as the same or similar numerals, and will not be discussed in detail as follows. For the sake of simplicity, the package component 140 and the underfill 150 may be omitted in this embodiment. As shown in FIG. 4, one of the vent holes 114 may be formed in the recess 112. To be more specific, one opening 113 (for example, referring to FIG. 1D) in the recess 112 may serve as a vent hole 114 without forming the conductive connector 120. That is to say, the locations of the vent holes 114 may be adjustable based on the present disclosure.

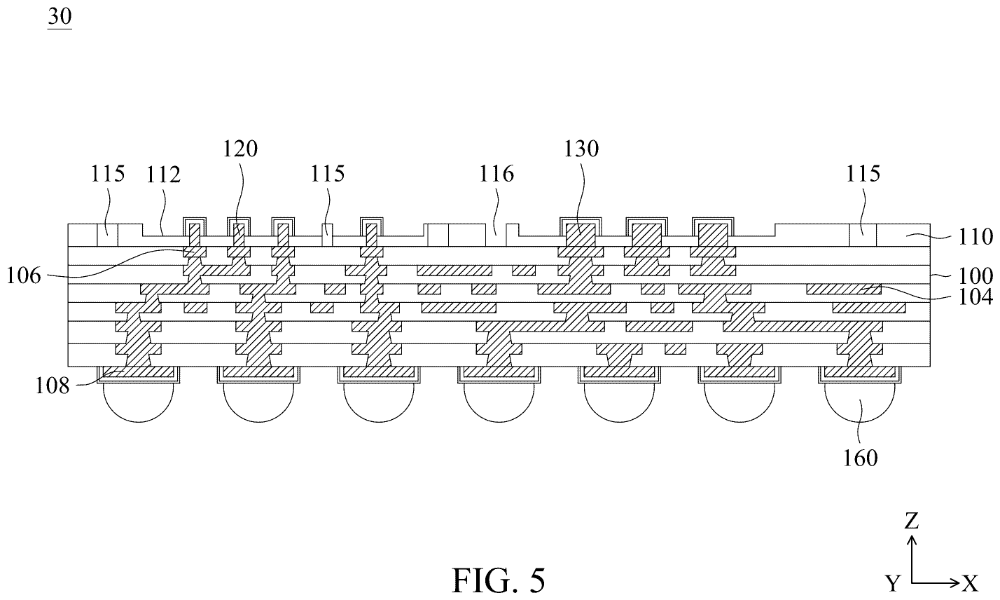

FIG. 5 illustrates a cross-sectional view of the package structure 30 in accordance with some embodiments. It should be noted that the package structure in this embodiment may include the same or similar portions or elements as those of the package structure 20 in FIG. 4. For the sake of brevity, these portions or elements will be denoted as the same or similar numerals, and will not be discussed in detail as follows. For the sake of simplicity, the package component 140 and the underfill 150 may be omitted in this embodiment. As shown in FIG. 5, a dielectric material 115 is filled in the vent holes 114, and a top surface of the dielectric material 115 is substantially level with a top surface of the inorganic substrate 110. In some embodiments, the dielectric material 115 may include the same material as the dielectric layers 102. However, the present disclosure is not limited thereto. With the arrangement of the dielectric material 115, the vent holes 114 may be prevented from foreign particles, and the gas or moisture may still be discharged from the underlying package substrate 100.

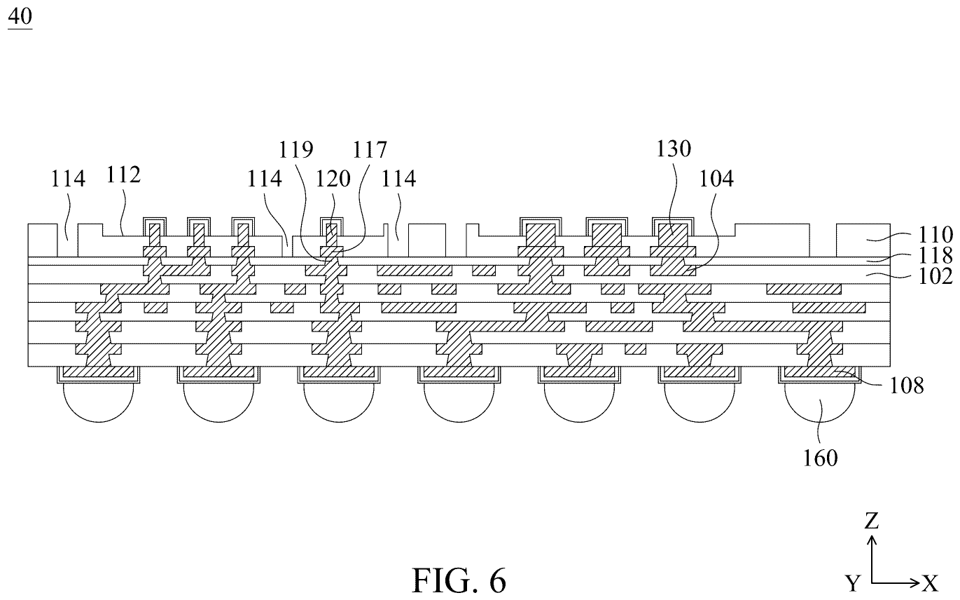

FIG. 6 illustrates a cross-sectional view of the package structure 40 in accordance with some embodiments. It should be noted that the package structure 40 in this embodiment may include the same or similar portions or elements as those of the package structure 20 in FIG. 4. For the sake of brevity, these portions or elements will be denoted as the same or similar numerals, and will not be discussed in detail as follows. For the sake of simplicity, the package component 140 and the underfill 150 may be omitted in this embodiment. For example, as shown in FIG. 6, the package structure 40 includes a dielectric layer 118, and a plurality of conductive patterns 117 formed in the dielectric layer 118. In addition, a plurality of conductive patterns 119 are formed over the conductive patterns 117 and electrically connected to the conductive connectors 120 and 130. In some embodiments, the inorganic substrate 110 may be disposed over the dielectric layer 118 after the conductive patterns 119 are formed. As a result, the conductive connectors 120 and 130 may be aligned with the conductive patterns 119 with less effort, reducing the process difficulty.

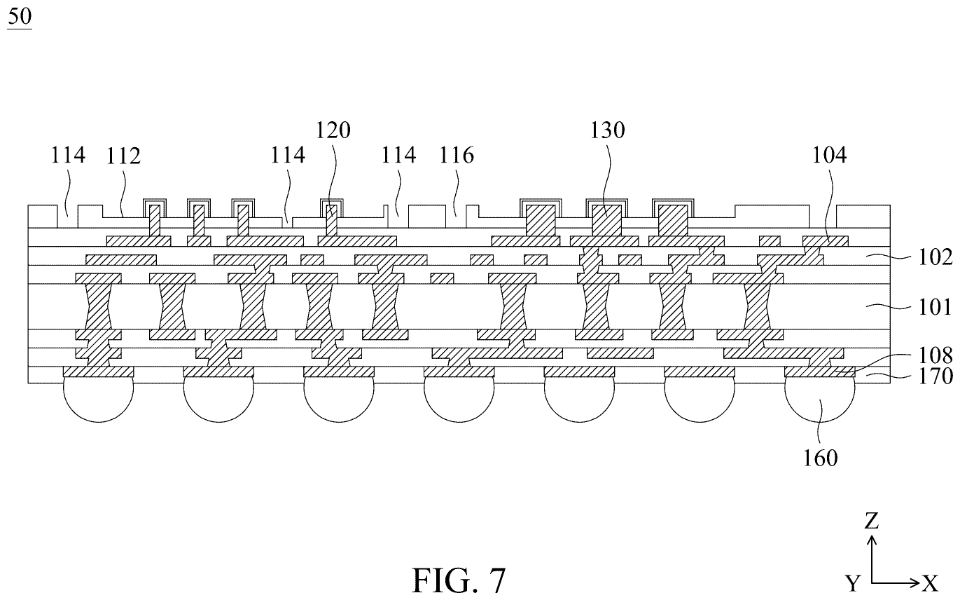

FIG. 7 illustrates a cross-sectional view of the package structure 50 in accordance with some embodiments. It should be noted that the package structure 50 in this embodiment may include the same or similar portions or elements as those of the package structure 20 in FIG. 4. For the sake of brevity, these portions or elements will be denoted as the same or similar numerals, and will not be discussed in detail as follows. For the sake of simplicity, the package component 140 and the underfill 150 may be omitted in this embodiment. As shown in FIG. 7, the package substrate 100 includes a substrate core 101, such as a fiberglass reinforced resin core. One example core material is fiberglass resin. Alternatives for the core material include bismaleimide-triazine (BT) resin, or alternatively, other PCB materials or films. Build up films or other laminates may be used for the package substrate 100. In some embodiments, a plurality of through holes are formed in the substrate core 101 for the formation of the conductive patterns 104. In some embodiments, the via portion 122 of the conductive connectors 120 extends into the uppermost dielectric layer 102 and electrically connected to the conductive patterns 104. As a result, the contact pads 106 may be omitted, reducing the process time and cost of the package structure 50.

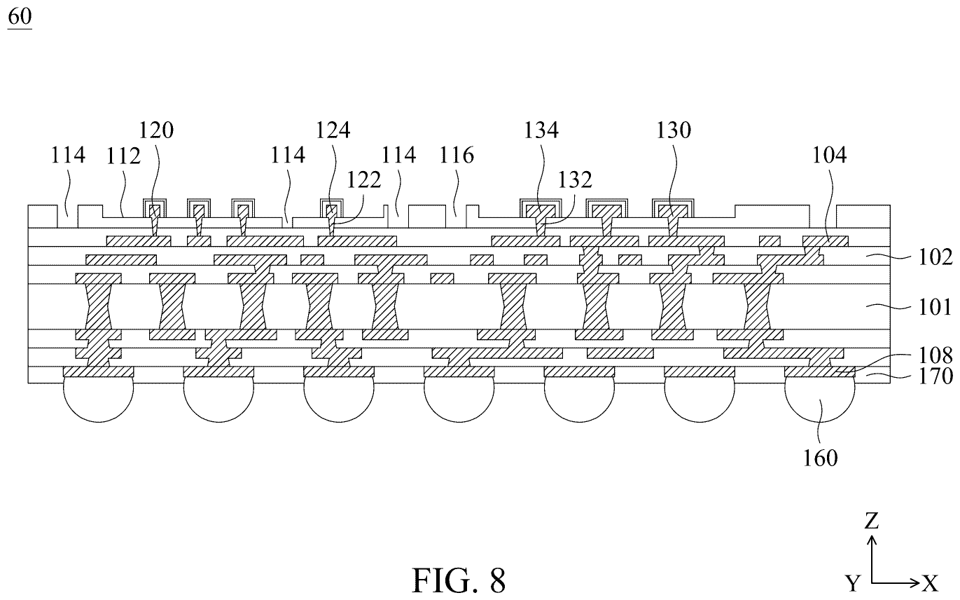

FIG. 8 illustrates a cross-sectional view of the package structure 60 in accordance with some embodiments. It should be noted that the package structure 60 in this embodiment may include the same or similar portions or elements as those of the package structure 50 in FIG. 7. For the sake of brevity, these portions or elements will be denoted as the same or similar numerals, and will not be discussed in detail as follows. For the sake of simplicity, the package component 140 and the underfill 150 may be omitted in this embodiment. As shown in FIG. 8, the via portions 122 of the conductive connectors 120 and the via portions 132 of the conductive connectors 130 each have a tapered profile in the cross-sectional view. In some embodiments, the diameter of the via portions 122 may be in a range from about 10 μm to about 90 μm. The diameter of the via portions 132 may be in a range from about 50 μm to about 480 μm. In some embodiments, a solder resist layer 170 is selectively formed over the dielectric layer 102. In some embodiments, the solder resist layer 170 is formed to cover the contact pads 108. In some embodiments, the solder resist layer 170 is used to protect the surface of the package structure 60 from external damage. However, the present disclosure is not limited thereto.

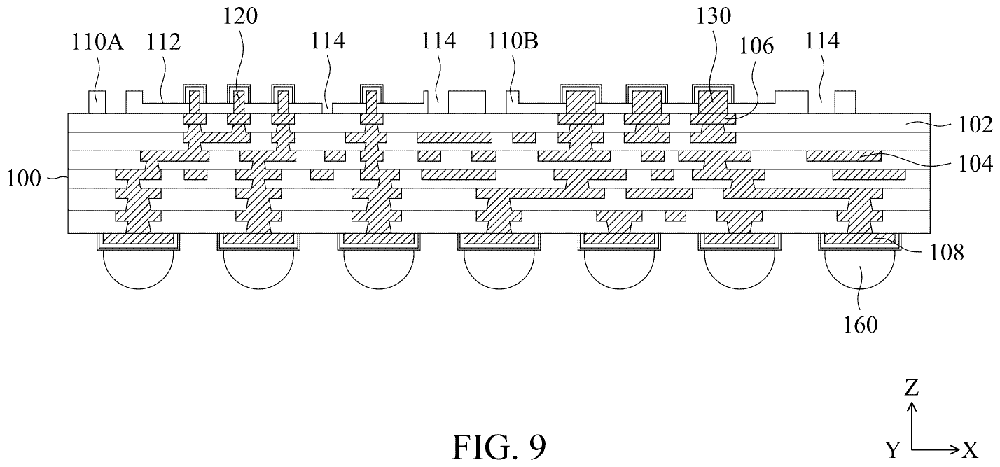

FIG. 9 illustrates a cross-sectional view of the package structure 70 in accordance with some embodiments. It should be noted that the package structure 70 in this embodiment may include the same or similar portions or elements as those of the package structure 10 in FIG. 1H. For the sake of brevity, these portions or elements will be denoted as the same or similar numerals, and will not be discussed in detail as follows. For the sake of simplicity, the package component 140 and the underfill 150 may be omitted in this embodiment. As shown in FIG. 9, the inorganic substrate 110 includes a plurality of portions 110A and 110B that are separated from each other. As a result, the material and cost of the inorganic substrate 110 may be reduced.

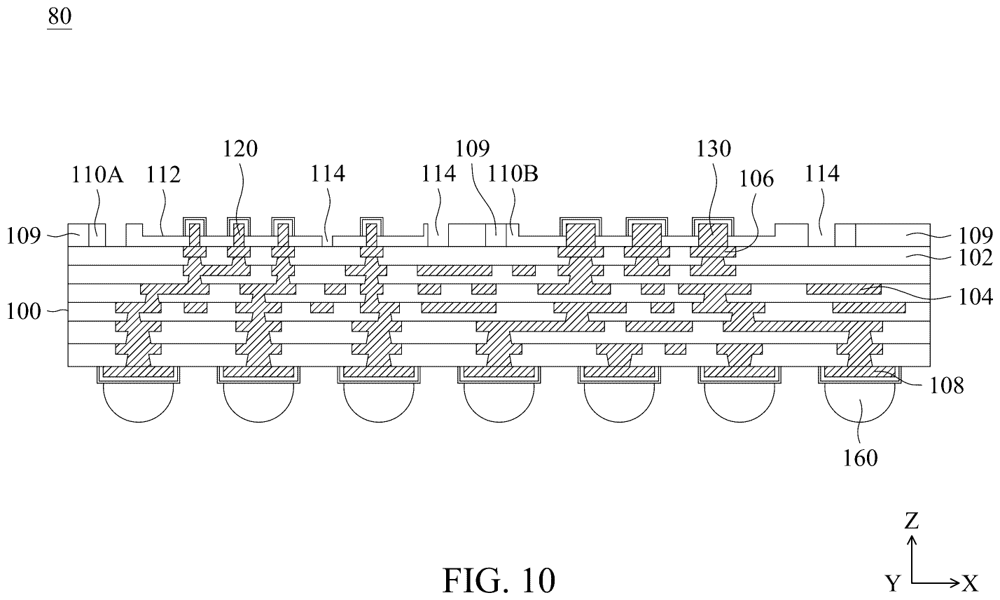

FIG. 10 illustrates a cross-sectional view of the package structure 80 in accordance with some embodiments. It should be noted that the package structure 80 in this embodiment may include the same or similar portions or elements as those of the package structure 70 in FIG. 9. For the sake of brevity, these portions or elements will be denoted as the same or similar numerals, and will not be discussed in detail as follows. For the sake of simplicity, the package component 140 and the underfill 150 may be omitted in this embodiment. As shown in FIG. 10, the package substrate 100 includes a plurality of protruding portions 109, and a top surface of the protruding portions 109 is substantially level with a top surface of the inorganic substrate 110. In some embodiments, the protruding portions 109 may fill the space between the adjacent portions 110A and 110B of the inorganic substrate 110. Accordingly, the inorganic substrate 110 may be disposed over the package substrate 100 more stably.

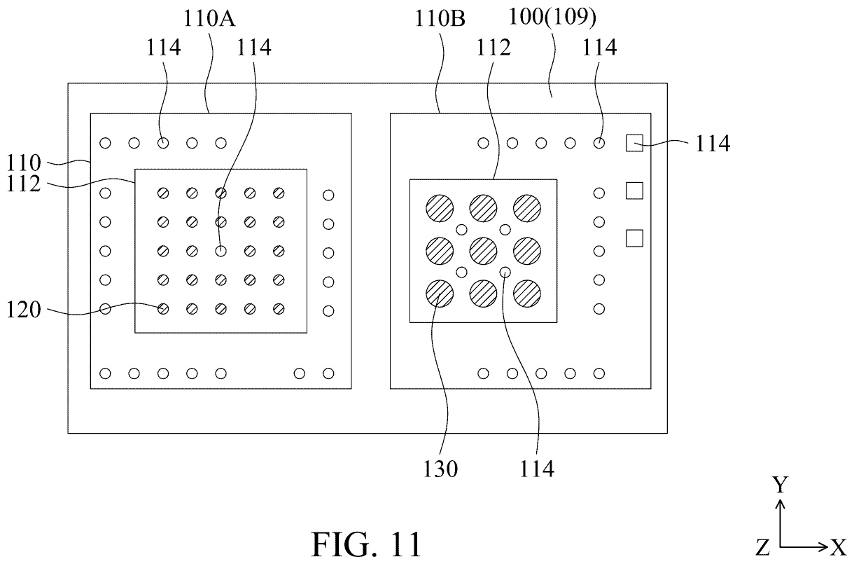

FIG. 11 illustrates a top view of the package structure 80 in accordance with some embodiments. It should be noted that the package structure in this embodiment may include the same or similar portions or elements as those of the package structure 10 in FIG. 3. For the sake of brevity, these portions or elements will be denoted as the same or similar numerals, and will not be discussed in detail as follows. As shown in FIG. 11, the separated portions 110A and 110B of the inorganic substrate 110 expose the edges of the underlying package substrate 100 (for example, the protruding portions 109).

Embodiments of package structures and method for fabricating the same are provided. The package structure includes an inorganic substrate over the package substrate. For example, the inorganic substrate may be made of alkaline earth boro-aluminosilicate, including elements such as Si, B, Al, Be, Ca, Na, O, etc. The arrangement of the inorganic substrate may help to reduce the coefficients of thermal expansion (CTE) mismatch between the substrate and the chips. Accordingly, the package reliability may be improved. In addition, a plurality of vent holes may be formed in the inorganic substrate so as to facilitate the gas or moisture discharged from the underlying substrate. Furthermore, a trench may be formed in the inorganic substrate so as to contain overflowing molding material (if present). Various embodiments are provided regarding the formation of the conductive connectors, increasing the process flexibility of the package structure.

In some embodiments, a package structure is provided. The package structure includes a package substrate and an inorganic substrate over the package substrate. The package structure includes a package component over the inorganic substrate. The package structure includes a plurality of conductive connectors penetrating the inorganic substrate and electrically connected to the package component and the package substrate The package structure also includes an underfill formed around the conductive connectors and between the package component and the inorganic substrate.

In some embodiments, a package structure is provided. The package structure includes a package substrate and a glass substrate over the package substrate. The package structure includes a plurality of conductive connectors, each of the conductive connectors includes a via portion embedded in the glass substrate and a pad portion over the glass substrate and electrically connected to the via portion. The package structure includes a package component over the glass substrate and electrically connected to the package substrate via the conductive connectors. The package structure also includes an underfill formed around the conductive connectors and between the package component and the glass substrate.

In some embodiments, a method for fabricating a package structure is provided. The method includes disposing a glass substrate over a package substrate. The method includes forming a plurality of openings in the glass substrate. The method includes forming a plurality of conductive connectors in the openings. The method includes bonding a package component to the conductive connectors. The method also includes forming an underfill between the glass substrate and the package component.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a package substrate;
an inorganic substrate over the package substrate;
a package component over the inorganic substrate;
a plurality of conductive connectors penetrating the inorganic substrate and electrically connected to the package component and the package substrate; and
an underfill formed around the conductive connectors and between the package component and the inorganic substrate.

2. The package structure as claimed in claim 1, wherein the inorganic substrate comprises alkaline earth boro-aluminosilicate.

3. The package structure as claimed in claim 1, wherein a plurality of vent holes are formed in the inorganic substrate.

4. The package structure as claimed in claim 3, wherein a dielectric material is filled in the vent holes.

5. The package structure as claimed in claim 3, wherein a width of the vent holes is ranged from about 10 μm to about 200 μm.

6. The package structure as claimed in claim 1, wherein a recess is formed in the inorganic substrate for receiving the package component.

7. The package structure as claimed in claim 6, wherein a trench is formed in the inorganic substrate, and the trench extends in parallel with an edge of the recess.

8. A package structure, comprising:
a package substrate;
a glass substrate over the package substrate;
a plurality of conductive connectors, wherein each of the conductive connectors comprises:
a via portion embedded in the glass substrate; and
a pad portion over the glass substrate and electrically connected to the via portion;
a package component over the glass substrate and electrically connected to the package substrate via the conductive connectors; and
an underfill formed around the conductive connectors and between the package component and the glass substrate.

9. The package structure as claimed in claim 8, wherein a recess is formed in the inorganic substrate for receiving the package component

10. The package structure as claimed in claim 9, wherein a plurality of vent holes are formed in the recess of the inorganic substrate.

11. The package structure as claimed in claim 8, wherein a thickness of the glass substrate is ranged from about 20 μm to about 250 μm.

12. The package structure as claimed in claim 8, wherein a trench is formed in the glass substrate, and a width of trench is ranged from about 25 μm to about 100 μm.

13. The package structure as claimed in claim 8, wherein the via portions of the conductive connectors each have a tapered profile in a cross-sectional view.

14. The package structure as claimed in claim 8, wherein the glass substrate comprises a plurality of portions separated from each other.

15. The package structure as claimed in claim 14, wherein the package substrate comprises a protruding portion, and a top surface of the protruding portion is substantially level with a top surface of the glass substrate.

16. A method for fabricating a package structure, comprising:
disposing a glass substrate over a package substrate;
forming a plurality of openings in the glass substrate;
forming a plurality of conductive connectors in the openings;
bonding a package component to the conductive connectors; and
forming an underfill between the glass substrate and the package component.

17. The package structure as claimed in claim 16, further comprising:
forming a recess in the glass substrate, wherein the openings are formed in the recess.

18. The package structure as claimed in claim 16, wherein forming a plurality of openings in the glass substrate further comprises:
forming a plurality of vent holes exposing the package substrate.

19. The package structure as claimed in claim 18, further comprising:
filling a dielectric material in the vent holes, wherein a top surface of the dielectric material is substantially level with a top surface of the glass substrate.

20. The package structure as claimed in claim 16, further comprising:
performing a surface treatment process to the conductive connectors before the package component is bonded to the conductive connectors.
